(19) United States
(12) Patent Application Publication
(10) Pub. No.: US 2026/0063722 A1
(43) Pub. Date: Mar. 5, 2026

(54) TECHNIQUES FOR ESTIMATING OPEN CIRCUIT POTENTIAL IN LITHIUM-ION BATTERIES WITHOUT ELECTRODE TEARDOWN

(71) Applicant: FCA US LLC, Auburn Hills, MI (US)

(72) Inventors: Satyam Panchal, Auburn Hills, MI (US); Guang Chen, Auburn Hills, MI (US); Vinicius Pierre, Auburn Hills, MI (US); Massimo Cancian, Auburn Hills, MI (US); Marcello Telloni, Columbus, OH (US); Faissal El Idrissi, Columbus, OH (US); Prashanth Ramesh, Columbus, OH (US); Marcello Canova, Columbus, OH (US)

(21) Appl. No.: 18/819,608

(22) Filed: Aug. 29, 2024

(51) Int. Cl. G01R 31/367; G01R 31/3835

(52) U.S. Cl. CPC G01R 31/367; G01R 31/3835

(57) ABSTRACT

An open-circuit potential (OCP) estimation method includes measuring a set of operating parameters of a battery cell of a battery system, the battery cell being a lithium-ion type battery cell and comprising two electrodes, and performing an OCP estimation process based on the measured set of operating parameters, the OCP estimation process further including obtaining known information relating to the two electrodes, identifying one of the two electrodes as a known electrode based on the known information, applying a physics-based model to reconstruct an OCP curve for the known electrode, determining lithiation ranges of the other of the two electrodes based on experimental test results for the battery cell, reconstructing an OCP curve for the other of the two electrodes based on its lithiation ranges, and generating a final estimate of the OCP of the two electrodes of the battery cell based on the reconstructed OCP curves.

### FIELD

The present application generally relates to electrified vehicles and, more particularly, to techniques for estimating open circuit potential in lithium-ion batteries without electrode teardown.

### BACKGROUND

An electrified vehicle includes a battery system configured to output electrical energy (i.e., current) to power one or more electric motors. One example battery system comprises a plurality of lithium-ion (Li-ion) type battery cells. One of the most important calibration tasks for Li-ion type battery systems is to match cell open-circuit voltage (OCV) and nominal capacity, which requires knowledge of open-circuit potentials (OCP) of the electrodes. Modeling the OCP curves as functions of the degree of lithiation of each electrode is also critical for accurate prediction of durability analysis and state of health (SOH) estimation. Conventional OCP data collection involves disassembling a cell to isolate the positive (cathode) and negative (anode) electrodes and building and testing a laboratory-grade “half-cell.” This conventional teardown and measurement process is very expensive and is potentially dangerous. Accordingly, while such conventional battery system OCP estimation techniques do work for their intended purpose, there exists an opportunity for improvement in the relevant art.

### SUMMARY

According to one example aspect of the invention, an open-circuit potential (OCP) estimation system for a battery system of an electrified vehicle is presented. In one exemplary implementation, the OCP estimation system comprises a set of sensors configured to measure a set of operating parameters of a battery cell of the battery system, the battery cell being a lithium-ion type battery cell and comprising two electrodes, and a computing device configured to perform an OCP estimation process based on the measured set of operating parameters, the OCP estimation process further including obtaining known information relating to the two electrodes, identifying one of the two electrodes as a known electrode based on the known information, applying a physics-based model to reconstruct an OCP curve for the known electrode, determining lithiation ranges of the other of the two electrodes based on experimental test results for the battery cell, reconstructing an OCP curve for the other of the two electrodes based on its lithiation ranges, and generating a final estimate of the OCP of the two electrodes of the battery cell based on the reconstructed OCP curves.

In some implementations, the battery cell is not physically disassembled. In some implementations, the known information for the two electrodes includes properties of materials forming the two electrodes, and wherein the known electrode is identified as having more known information. In some implementations, the computing device is further configured to determine an electrode data quality score for each of the two electrodes based on the known information and identify the known electrode as having the higher electrode data quality score. In some implementations, the computing device is further configured to apply a multi-scale-multi-reaction (MSMR) model to reconstruct the OCP curve for the known electrode based on its known information. In some implementations, the computing device is further configured to correct the reconstructed OCP curve for the known electrode based on whether its phase transition locations are known and whether peaks predicted by the MSMR model are coherent.

In some implementations, the computing device is further configured to perform an experimental test for the battery cell as a whole to determine the experimental test results including an open-circuit voltage (OCV) measurement for the battery cell. In some implementations, the computing device is further configured to determine an initial guess of the lithiation ranges for the other of the two electrodes of the battery cell and to shift and/or rescale the reconstructed OCP curve for the other of the two electrodes to match with the battery cell OCV measurement. In some implementations, the computing device is further configured to solve a constrained optimization problem to generate the final estimate of the OCP of the two electrodes of the battery cell. In some implementations, the computing device is further configured to perform an error analysis for the final estimate of the OCP of the two electrodes of the battery cell, the error analysis including (i) root-mean-square (RMS) based terminal voltage validation, (ii) visual inspection terminal voltage validation, (iii) electrode consistence analysis, and (iv) boundary adherence analysis.

According to another example aspect of the invention, an OCP estimation method for a battery system of an electrified vehicle is presented. In one exemplary implementation, the OCP estimation system comprises measuring, by a set of sensors, a set of operating parameters of a battery cell of the battery system, the battery cell being a lithium-ion type battery cell and comprising two electrodes, and performing, by a computing device associated with the electrified vehicle, an OCP estimation process based on the measured set of operating parameters, the OCP estimation process further including obtaining known information relating to the two electrodes, identifying one of the two electrodes as a known electrode based on the known information, applying a physics-based model to reconstruct an OCP curve for the known electrode, determining lithiation ranges of the other of the two electrodes based on experimental test results for the battery cell, reconstructing an OCP curve for the other of the two electrodes based on its lithiation ranges, and generating a final estimate of the OCP of the two electrodes of the battery cell based on the reconstructed OCP curves.

In some implementations, the OCP estimation method does not include physically disassembling the battery cell. In some implementations, the known information for the two electrodes includes properties of materials forming the two electrodes, and wherein the known electrode is identified as having more known information. In some implementations, the OCP estimation method further comprises determining, by the computing device, an electrode data quality score for each of the two electrodes based on the known information and identify the known electrode as having the higher electrode data quality score. In some implementations, the OCP estimation method further comprises applying, by the computing device, an MSMR model to reconstruct the OCP curve for the known electrode based on its known information. In some implementations, the OCP estimation method further comprises correcting, by the computing device, the reconstructed OCP curve for the known electrode based on whether its phase transition locations are known and whether peaks predicted by the MSMR model are coherent.

In some implementations, the OCP estimation method further comprises performing, by the computing device, an experimental test for the battery cell as a whole to determine the experimental test results including an OCV measurement for the battery cell. In some implementations, the OCP estimation method further comprises determining, by the computing device, an initial guess of the lithiation ranges for the other of the two electrodes of the battery cell and then shifting and/or rescaling, by the computing device, the reconstructed OCP curve for the other of the two electrodes to match with the battery cell OCV measurement. In some implementations, the OCP estimation method further comprises solving, by the computing device, a constrained optimization problem to generate the final estimate of the OCP of the two electrodes of the battery cell. In some implementations, the OCP estimation method further comprises performing, by the computing device, an error analysis for the final estimate of the OCP of the two electrodes of the battery cell, the error analysis including (i) RMS based terminal voltage validation, (ii) visual inspection terminal voltage validation, (iii) electrode consistence analysis, and (iv) boundary adherence analysis.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 illustrates a functional block diagram of an electrified vehicle having an example battery open-circuit potential (OCP) estimation system according to the principles of the present application;

FIG. 2 illustrates a flow diagram of an example battery OCP estimation method for an electrified vehicle according to the principles of the present application;

FIG. 3 illustrates a table including an example summary of known information regarding electrode material attributes according to the principles of the present application;

FIG. 4 illustrates a table depicting an example electrode grading system for identifying which electrode is reconstructed according to the principles of the present application;

FIGS. 5A-5B illustrate plots depicting example peak realignment logic as part of the correction of the reconstructed OCP curve according to the principles of the present application;

FIGS. 6A-6C illustrate plots depicting an example graphical representation of determining an initial guess for lithiation ranges according to the principles of the present application;

FIG. 7 illustrates plots depicting an example identification of common peaks between the differential capacity curves of the full cell and the known electrode according to the principles of the present application;

FIG. 8 illustrates plots depicting an example alignment of the known electrode and full cell peaks according to the principles of the present application;

FIG. 9 illustrates plots depicting data loading and pre-processing for estimation of the unknown electrode OCP from the cell open-circuit voltage (OCV) measurements according to the principles of the present application; and

FIG. 10 illustrates a flow diagram of an example error analysis method including cell OCV validation, electrode OCP physical consistency, and optimization variable saturation according to the principles of the present application.

### DESCRIPTION

As previously discussed, one example configuration for a high voltage battery system for an electrified vehicle comprises a plurality of lithium-ion (Li-ion) type battery cells. Physics-based electrochemical models of Li-ion batteries (a pseudo-two-dimensional (P2D) model, an extended single particle model (ESPM), etc.) feature excellent accuracy for predicting the cell voltage response during different test conditions. These models, however, require careful calibration of specific physical parameters and functions to achieve reasonable predictive capabilities. One of the most important calibration tasks is to match the cell open-circuit voltage (OCV) and nominal capacity, which requires knowledge of the open circuit potentials (OCP) of the individual electrodes. Modeling the OCP curves as functions of the degree of lithiation of each electrode is also critical for accurate prediction of durability analysis and state of health (SOH) estimation. More specifically, accurate OCP data allows one to perform incremental capacity analysis (dQ/dV), which is important for characterizing cell behavior and determining the degradation mechanisms (loss of cyclable lithium, loss of active material, etc.) during calendar and/or cycle aging. The OCP curve is generally specified as a map that represents the relationship between the concentration of lithium in the electrode (x) and the corresponding OCP, or U(x).

Achieving an accurate OCP prediction entails the following steps. First, a cell is disassembled (also known as “cell teardown”) to isolate the positive (cathode) and negative (anode) electrodes and a laboratory-grade evaluation cells are built containing sample material from each individual electrode coupled with a reference electrode (lithium metal). This setup is known as “half-cell” and permits measurements of properties of the active material of an individual electrode. Second, very precise measurements are conducted at near-equilibrium conditions of individual electrodes using half-cell testing methods, so as to eliminate as much as possible the impact of noise and process irreversibility (polarization, transport, ohmic losses, etc.) from the voltage measurements. Third and finally, equipment is utilized providing high resolution in current and voltage data, which is essential for accurately capturing phase transitions (plateaus) occurring as electrode materials lithiate/delithiate. As mentioned above, conducting cell teardown and measurements on individual electrodes is extremely expensive and potentially dangerous. For example, it could take approximately 8-9 months for a cell to be fully discharged such that it can safely be disassembled for analysis. For this reason, information on electrode OCP is generally obtained by leveraging existing knowledge in technical literature or prior experiments, which presents significant limitation in availability and quality of the data.

Accordingly, techniques are presented herein that produce an accurate representation of the OCP curve for both electrodes by leveraging known information and experimental test results conducted on a full (commercial) cell. The procedure involves initiating and conducting a single constant current (CC) experiment on the full cell from the available or known information on electrode materials and partial OCP data of one of the electrodes. From this premise, the procedure will reconstruct the OCP of the first electrode from partial data and then identify the OCP of the second electrode by leveraging the cell test data and solving a nonlinear constrained optimization problem. The procedure described in this application eliminates the need for cell teardown procedures (which involves the use of costly facilities and equipment, potential hazards, and significant preparation time), and generates OCP curves that offer precise estimates of the cell terminal voltage and dQ/dV diagrams. Additionally, the OCP curves reconstructed from this procedure exhibit a physically consistent representation of the chemical characteristics of the materials, ensuring that the OCP plateaus corresponding to phase transitioned are associated to the correct potential ranges for the specific electrode material, and the overall profile of the curves is consistent with literature and scientific knowledge.

It will be appreciated that there may exist methods that utilize information obtained from known sources (e.g., literature) to determine OCP curves, after which several capacity-related parameters need to be tuned to match the cell OCV. The use of known data could introduce errors. In one example scenario, data in the existing literature may not match exactly the physical and electrochemical properties of a specific electrode material utilized in an individual cell. In another example scenario, importing data from a graphical representation in a reference (technical paper or website) could lead to errors in determining the location of the (x-y) coordinates. In another example scenario, the exact test conditions (particularly the C-rate) may not be fully known, which make it difficult to evaluate whether the test was conducted at near-equilibrium conditions to correctly measure the electrode OCP. In yet another example scenario, the resolution of data in graphical form may not be sufficient to reconstruct the plateaus corresponding to the phase transitions in the electrode material during lithiation or delithiation.

The present application addresses these aforementioned challenges by developing a specific nine (9) step procedure that leases to the data enhancement and OCP reconstruction for both electrodes in an Li-ion commercial cell without resorting to cell teardown. The procedure is also designed to identify which electrode (i.e., the cathode or anode) is more suitable for reconstruction and which one is better to be retrieved from known information and then adjusted. This is achieved by utilizing experimental data collected on the cell terminal voltage and leveraging relevant physical information about the electrode's material sourced from the known information. Finally, the procedure includes a systematic error detection strategy to assess reliability of the results proposing potential remediation solutions for result enhancement. Potential benefits of the techniques of the present application include decreased costs and increased safety by avoiding or eliminating the cell teardown process. Potential benefits also include the ability to better source battery packs/systems from suppliers without having to do a lengthy/expensive analysis of the cell OCP and OCV properties.

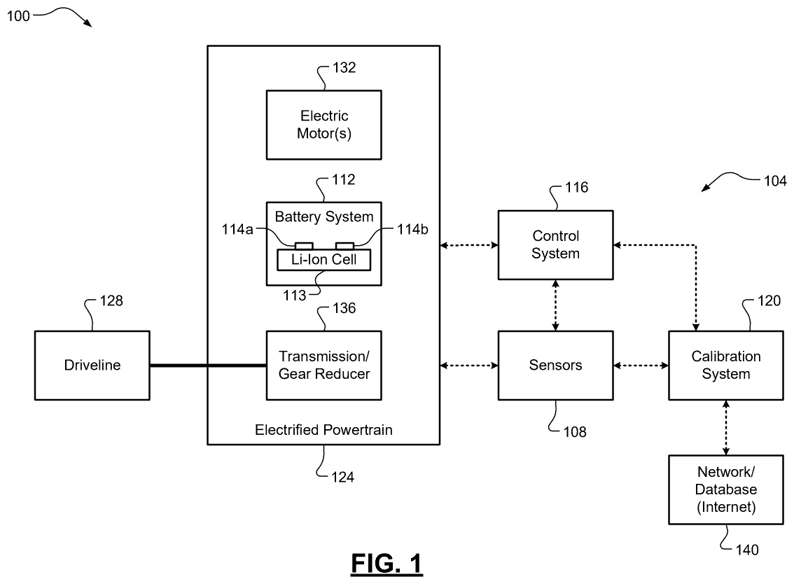

Referring now to FIG. 1, a functional block diagram of an electrified vehicle 100 having an example OCP estimation system 104 according to the principles of the present application is illustrated. The OCP estimation system comprises a plurality of sensors 108 configured to measure operating parameters of a high voltage battery pack or system 112, comprising a plurality of Li-ion type battery cells 113 each having a cathode 114a and an anode 114b (collectively, “electrodes 114”), and a computing device. The computing device could be a controller or control system 116 of the electrified vehicle 100 or a calibration system 120 of the electrified vehicle 100. The electrified vehicle 100 comprises an electrified powertrain 124 configured to generate and transfer drive torque to a driveline 128 for vehicle propulsion. The electrified powertrain 124 includes, for example, the high voltage battery system 112, which is configured to power one or more electric motors 132, which generate drive torque that is transferred to the driveline 128 via an optional transmission or gear reducer 136. The computing system of the OCP estimation system 104 will also have access to a database of known information (literature, experimental data, etc.), such as a local database 140 or a remote database via a network 140 (e.g., the Internet), also referred to herein as “known sources 140.”

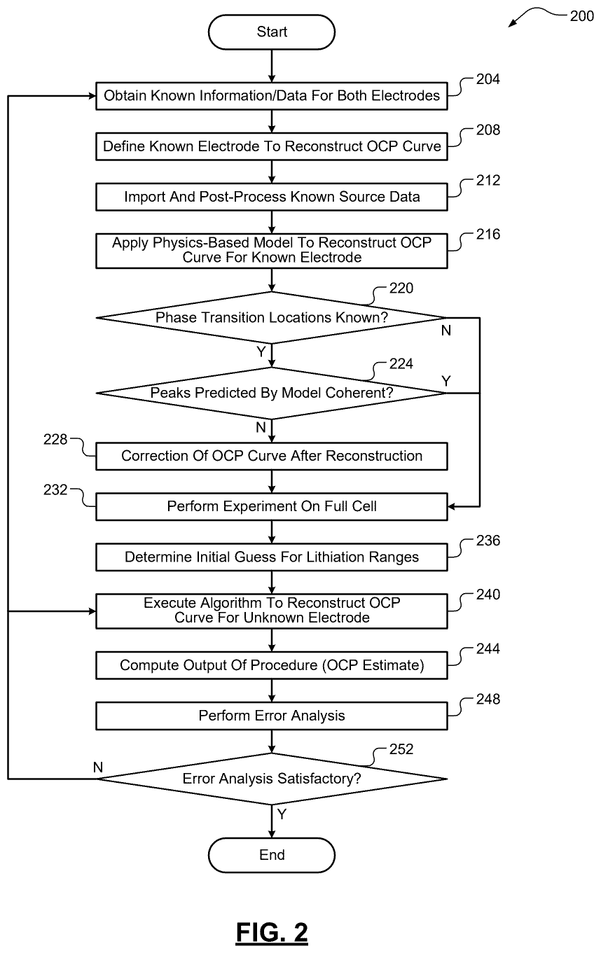

Referring now to FIG. 2, a flow diagram of an example SOP estimation method 200 for an electrified vehicle according to the principles of the present application is illustrated. While the method 200 specifically references the electrified vehicle 100 and its sub-components (e.g., Li-ion cell 113 having electrodes 114), it will be appreciated that the method 200 could be applicable to any Li-ion battery pack/system, including non-vehicle applications.

The method 200 starts from a knowledge of the type of materials utilized in the electrodes (cathode and anode) of a given Li-ion cell, utilizes a physics-based model predicting OCP of an electrode as functions of the degree of lithiation, and requires information from existing literature and data from a capacity test conducted on the full cell. The method 200 generally involves three different phases. First (1), technical literature and available databases are searched for sourcing non-proprietary data and information on electrode materials properties and OCP and apply a scoring system to assess data quality (steps 204-208). Based on the available information, the electrode for the reconstruction is determined or identified via a scoring system. Next (2), the OCP curves are reconstructed and estimated from sparse data (steps 212-244). The procedure applies the physics-based OCP prediction model and a large-scale optimization algorithm to conduct parameter identification, which results into the reconstruction of the OCP curves for the electrodes of the Li-ion cell and the joint determination of the lithiation range of each electrode. Finally (3), the results are verified and error analysis is performed (step 248-252), which involves a series of steps to troubleshoot modeling errors, allowing one to assess the accuracy and reliability of the outputs. The details of these nine (9) steps generally described above and shown in FIG. 2 will now be described in greater detail.

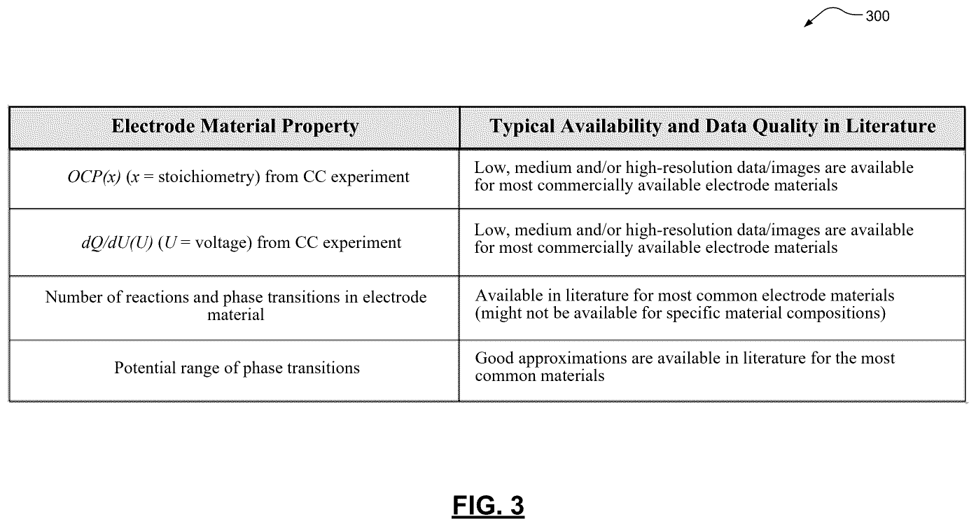

Step 204 involves obtaining (e.g., retrieving) information/data for both electrodes 114 from the known sources 140. More specifically, after conducting an exhaustive search of the known sources 140, existing information and data on electrode material properties are collected and classified, such as in a table 300 as depicted in FIG. 3. The content of the table 300 aims at providing guidance on the typical sources of information and specific data available for electrode materials from typical literature and state of the art resources, as well as the relative expectations in terms of data accuracy and information content. This table 300 informs the subsequent stages of the electrode OCP reconstruction procedure.

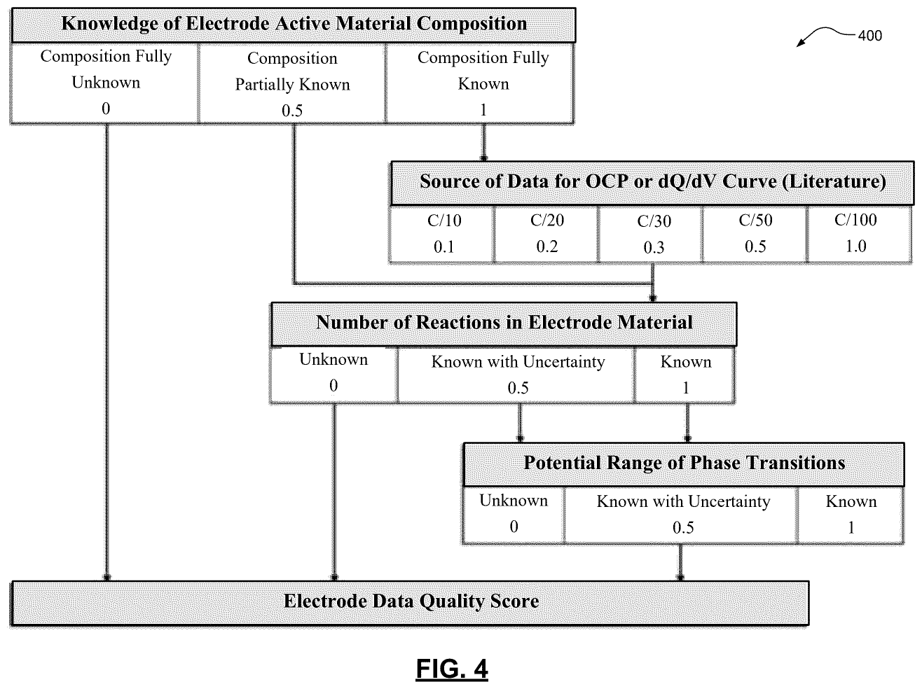

Step 208 involves defining or identifying the known (first) electrode for which the OCP curve will be reconstructed. Utilizing the information and data collected from literature following the indications outlined in the previous step, a scoring system is assigned to each of the cell electrodes, as illustrated in the table 400 of FIG. 4. For each electrode, the available information is classified according to three primary categories: (1) “fully unknown” (information on electrode material properties is not available in literature or from other data sources; (2) “known with uncertainty” (information for a specific electrode material is not available, but data for a comparable or similar material is available); or (3) “known” (information for a specific electrode material is fully available). The final score obtained (e.g., via the flow through table 400) determines the quality of the available information and allows one to define the known/first electrode (whose OCP curve is reconstructed and enhanced starting from the data set characterized by the highest quality) and the and unknown (second) electrode (for which a more complex estimation of the OCP curve is required due to the higher uncertainty in the available information).

Step 212 involves importing and post-processing data from the known sources 140. Acquiring the OCP of the known electrode necessitates manual sampling of points from graphic images or tables obtained from the known sources 140 conducted in step 204. The quality of the image may require the use of software for image resolution enhancement. To acquire data from OCP curves in graphical form, a MATLAB® based tool could be used to convert the image into data points. After importing the data points into MATLAB®, filtering and up-sampling are applied to achieve a smoother signal. In this step 212, two different scenarios may be encountered: (1) if the OCP data are already displayed as function of the normalized degree of lithiation—OCP(x)—no additional calculations are required; or (2) if differential capacity data is displayed in lieu of OCP data—dQ and dU (U)—the normalized degree of lithiation can be obtained by applying the following conversion:

$$x = \frac{\int \frac{dQ}{dU} d V}{{Q}_{nom}} \qquad ( 1 )$$

where dQ/dU represent the data points of the differential capacity plot, Q is the half-cell (electrode) capacity, Qₙₒₘ is the half-cell nominal capacity, and V the measured half-cell voltage during the test.

Step 216 involves applying a physics-based model to reconstruct the OCP of the known electrode. For example, a multi-scale-multi-reaction (MSMR) model could lead to an analytical representation of the dQ/dU curve of a Li-ion cell electrode of any material composition as function of the normalized lithium content. The model assumes that the electrode undergoes an arbitrary number N electrochemical reactions when lithiating/delithiating, which may overlap with each other leading to phase transitions. Based on the Nernst Equation and assuming that all reactions occur in parallel at equilibrium conditions (U=U₁=U₂= . . . =U_{N}), the model provides a set of equations that predicts the dQ/dU curve as function of the electrode equilibrium potential U:

$$( U ) = {\sum }_{j} \frac{{X}_{j}}{1 + exp [ \frac{f ( U - {U}_{j}^{0} )}{{w}_{j}} ]} j = 1 , … N \qquad ( 2 )$$

$$0 < x ( U ) < 1 , and$$

$$\frac{\partial x}{\partial U} = {\sum }_{j} \frac{\partial {x}_{j}}{\partial U} = {\sum }_{j} - \frac{{X}_{j}}{f} \frac{f {e}^{\frac{f ( U - {U}_{j}^{0} )}{{ω}_{j}}}}{{( 1 + {e}^{\frac{f ( U - {U}_{j}^{0} )}{{ω}_{j}}} )}^{2}} , \qquad ( 3 )$$

where f represents a physical constant

$$( f = F / RT ) , {U}_{j}^{0} , {X}_{j} ,$$

and ωⱼ represent model parameters, and N represents a number of reactions. The MSMR model offers a physics-based framework to obtain an analytical expression of the dQ/dU curve for a given electrode material, which can be fitted to the OCP data obtained in step 212. This model is adopted as a technique to enhance the quality of the representation of the OCP function U (x) and achieve higher resolution when predicting the dQ/dU peaks.

The fourth step of the nine steps of method 200 comprises steps 216-228. Step 216 is carried out as follows. First (1), a suitable data structure, parameters, and constraints are defined. Two signals are taken into consideration: U (x) and dx/dU (U). Obtaining dx/dU (U) data from the characterization of OCP(x) obtained by importing sparse data from literature requires numerically differentiating and inverting the data array and fine-tuning the derivative rate (ΔV) manually to achieve a good trade-off between noise and the quality of the resulting diagram of dx/dU (U). Then, a selection of the number of reactions N occurring in the material (with a tentative value obtained from step 204, if available) is made. The corresponding set of parameters and constraints, as summarized in Table 1 below, must be initialized to solve the optimization problem. These constraints establish the range within which the optimization algorithm will search for the parameters of the MSMR that best fit the data. While some of these parameters are arbitrarily defined, others can be more precisely determined by examining the peaks' position and width of the dx/dU (U) curve. Finally, an optimization weight W and the weight a used to assign different importance to various sections of the curves are set.

TABLE 1

| | Number of reactions in |
|---|---|
| N | electrode material |
| ΔV | Resolution on the electrode |
| | potential scale |
| ${U}_{0 , j}^{0} , {X}_{0 , j} , {w}_{0 , j} , j = 1 , … , N$ | Initial guess for MSMR model parameters |
| $Δ {U}_{j}^{0} , Δ {X}_{j} , Δ {w}_{j} , j = 1 , … , N$ | Range of variation for MSMR parameters |
| ${U}_{0 , j , peaks}^{0} , Δ {U}_{0 , j , peaks}^{0} , j = 1 , … , N$ | Information on peak locations in dx/dU diagram |
| W, α | Optimization weights |

Next (2), MSMR model parameters are identified. In this sub-step, the optimization algorithm for the identification of the MSMR model parameters is configured. Once the constraints of the optimization problem (as in Table 1) and the optimizer are initialized, the algorithm will be executed to generate a solution. The optimization problem for parameter identification is a large-scale, nonlinear problem, requiring a gradient-free, large-scale optimization algorithm to obtain a solution. For this problem, Particle Swarm Optimization (PSO) could be utilized, based on the Global Optimization Toolbox in MATLAB®. The objective function to minimize is as follows:

$${min}_{θ} J = ( 1 - W ) \cdot {J}_{1} + W \cdot {J}_{2} + {J}_{pen} , \qquad ( 4 )$$

subject to:

$${U}_{0 , j}^{0} - Δ {U}^{0} \leq {U}_{j}^{0} \leq {U}_{0 , j}^{0} + Δ {U}^{0} \qquad ( 5 a )$$

$${X}_{0 , j} - Δ X \leq {X}_{j} \leq {X}_{0 , j} + Δ X , and \qquad ( 5 b )$$

$${w}_{0 , j} - Δ w \leq {w}_{j} \leq {w}_{0 , j} + Δ w , \qquad ( 5 c )$$

$$where :$$

$${J}_{1} = \frac{\sqrt{\frac{1}{n} {\sum }_{i}^{n} {( ( {OC V}_{i} - ) \cdot α )}^{2}}}{{e}_{OC V , max}} , and \qquad ( 6 a )$$

$${J}_{2} = \frac{\sqrt{\frac{1}{n} {\sum }_{i}^{n} {( ( \frac{dx}{{d V}_{i}} - \frac{{d V}_{ι}}{} ) \cdot α )}^{2}}}{{e}_{\frac{dx}{d V} , max}} . \qquad ( 6 b )$$

The solution to this optimization problem procedure produces a set of [3×N] parameters for the MSMR model, where e_{OCV,max} and e_{dx/dV,max} are the maximum tolerable errors and Jₚₑₙ is a penalty term that accounts for the violation of physics-related constraints.

Finally (3), analytical and visual validation is performed. Once the parameters of the MSMR model are obtained via large-scale optimization, it is essential to conduct assessments, including evaluating the root-mean-square (RMS) error calculated for OCP(x) and dx/dU (U), along with a visual inspection to identify areas with elevated errors and assess their reasonableness. If the obtained results are unsatisfactory, a refinement of the constraints, optimization weight (N), or the weight on a may be iteratively adjusted to improve the results.

Step 228 involves the correction of the OCP curve after reconstruction, which depends on whether the phase transition locations are known (from step 204) and whether the peaks predicted by the model are coherent, as shown in intermediary decision steps 220 and 224. In other words, this step 228 is executed based on the information acquired in step 204. To perform a verification and correction of the reconstructed OCP curve, the potential range of the phase transitions exhibited by the electrode material, namely information on the locations of the main peaks in the dx/dU (U) profile must be found in literature. The objective of this step 228 is to refine the curve obtained with the MSMR model, ensuring a better alignment of the observed peaks with their expected location from theory or similar evidence in literature. Starting from the outcomes of step 216, this stage enables the integration of information sourced from literature with the calibrated MSMR model.

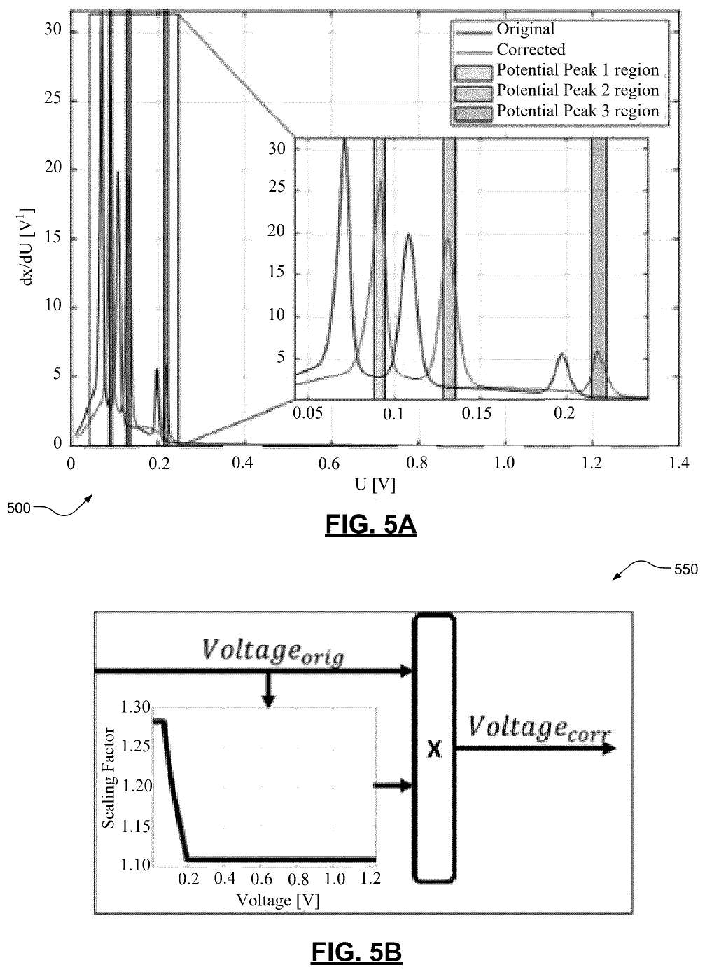

As an illustrative example, step 216 was applied to the data of a graphite negative electrode in the plots 500, 550 of FIGS. 5A-5B. The tuned MSMR model (back line) is compared against information collected from literature regarding the theoretical locations of the dx/dU peaks (highlighted regions). Step 224 involves verifying that the peaks predicted by the tuned MSMR model lie within the ranges obtained from literature and, in case a mismatch is noticed, the corresponding peaks need to be relocated. To move the locations of the peaks, a voltage-dependent scaling factor is generated such as the peaks result realigned, as shown in FIG. 5A. The corrected curve is generated by applying the logic represented in FIG. 5B. Despite the specific example shown here, this correction step can be applied to any type of material provided that the theoretical locations of its peaks are somewhat known.

Step 232 involves performing an experiment to measure the OCV of a full Li-ion cell. Terminal voltage data are collected from the cell under the conditions of a low constant current experiment (C/100, C/50), such as dynamic terms are intentionally not excited. The experiment aims to accurately detect phase transitions in the electrodes. Subsequently, voltage resampling and filtering are applied, and the SOC is computed as follows:

$$SOC ( t ) = \frac{1}{{Q}_{max}} \int I ( t ) dt . \qquad ( 7 )$$

Finally, the dSOC/dOCV (OCV) profile is calculated. The derivative rate is manually adjusted to generate a good trade-off between noise and the quality of the dSOC/dOCV (OCV) profile.

Step 236 involves determining an initial guess for the lithiation ranges. In the process of charging and discharging a cell, lithium ions move between electrodes through chemical reactions. However, not all lithium ions contained in the electrode material actively participate in these reactions, resulting into a portion remaining trapped within the electrode. This is an intentional design feature used to provide a buffer of lithium that can compensate the lithium losses occurring over the cell's operational lifespan due to degradation phenomena. Nevertheless, the trapped lithium introduces an additional layer of complexity when attempting to accurately predict the cell's terminal voltage, since the amount of trapped lithium is unknown and cannot be immediately quantified from simply measuring the cell terminal voltage. Therefore, the portion of lithium involved in the lithiation and delithiation processes must be estimated for each electrode. To this end, four additional parameters

$$( {x}_{n}^{0} , {x}_{n}^{f} , {x}_{p}^{0} , {x}_{p}^{f} )$$

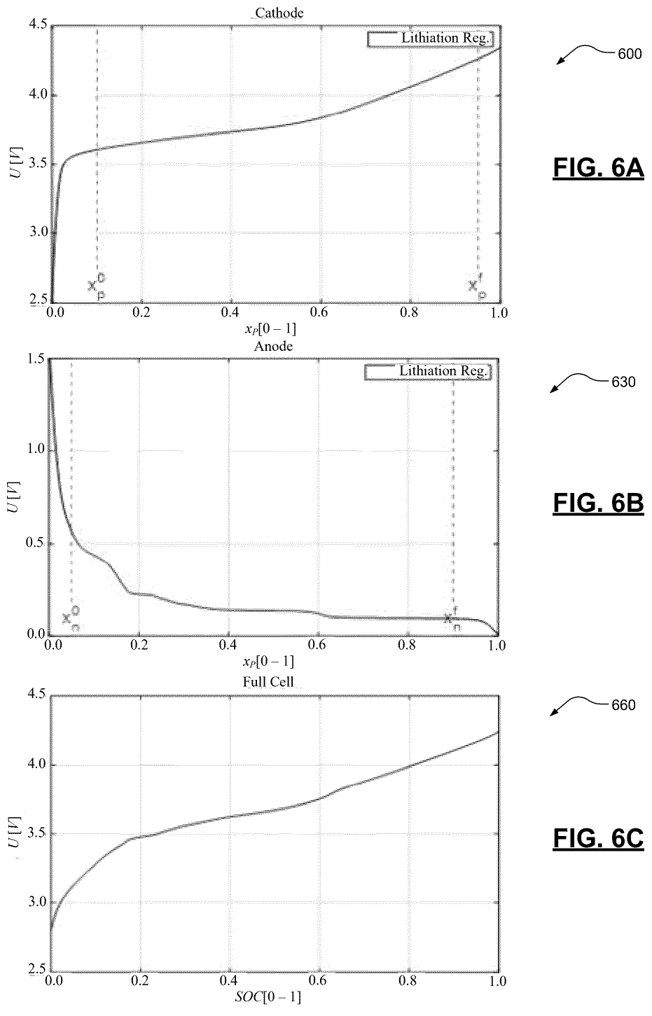

are introduced to determine the portion of the OCP of each electrode that is utilized during the cell's lithiation/delithiation. A graphical representation of this concept (highlighted areas) is illustrated in the plots 600, 630, and 660 of FIGS. 6A-6B. The parameters

$$( {x}_{n}^{0} , {x}_{n}^{f} , {x}_{p}^{0} , {x}_{p}^{f} )$$

define the lithiation ranges of the negative and positive electrodes of the cell, enable the shifting and rescaling of the OCP curves to match with the cell OCV. Once their value is determined, the terminal voltage is computed as follows:

$$OC V ( SOC ) = {U}_{p} ( {SOC}_{p} ( {\tilde{x}}_{p} ) ) - {U}_{n} ( {SOC}_{n} ( {\tilde{x}}_{n} ) ) \qquad ( 8 )$$

where:

$${SOC}_{p} ( {\tilde{x}}_{p} ) = \frac{{\tilde{x}}_{p} - {x}_{p}^{0}}{{x}_{p}^{f} - {x}_{p}^{0}} with {\tilde{x}}_{p} ∈ [ {x}_{p}^{0} , {x}_{p}^{f} ] , and$$

$${SOC}_{n} ( {\tilde{x}}_{n} ) = \frac{{\tilde{x}}_{n} - {x}_{n}^{0}}{{x}_{n}^{f} - {x}_{n}^{0}} with {\tilde{x}}_{n} ∈ [ {x}_{n}^{0} , {x}_{n}^{f} ] .$$

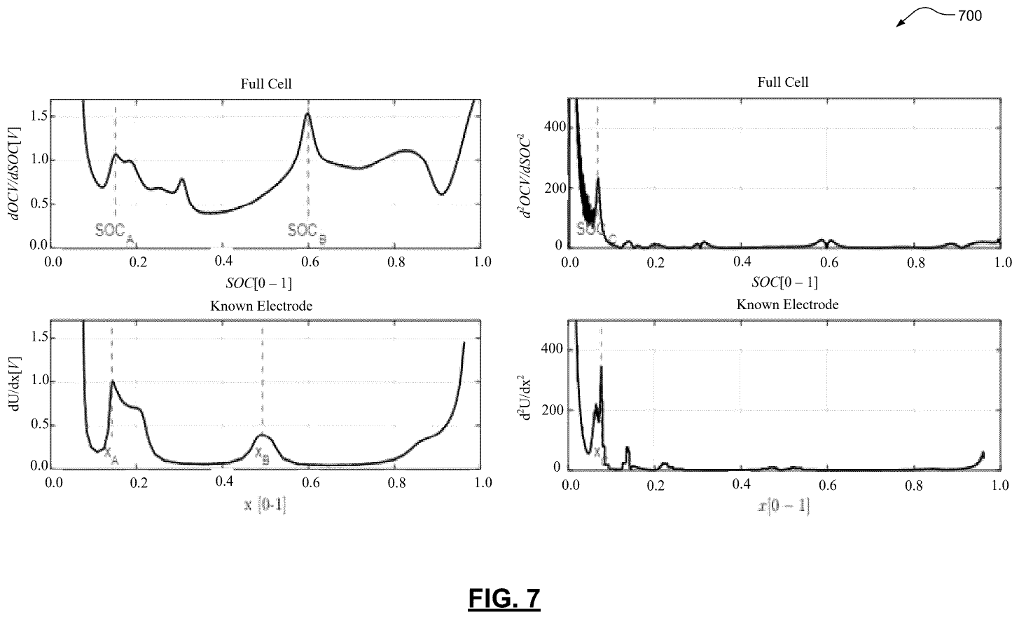

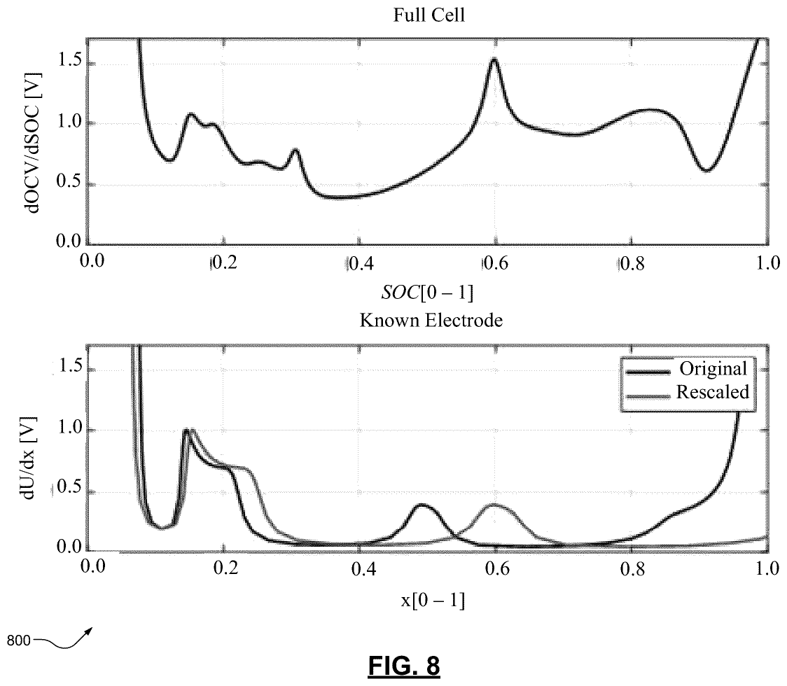

This concept holds significant importance in structuring the optimization problem. Along with reconstructing the OCP curves across the full stoichiometry range of x=[0 1], it is equally important to identify the lithiation ranges for the anode and cathode such that the predicted terminal voltage OCV accurately matches experimental data. Since at the beginning of the process one of the OCP curves is completely unknown, it is not possible to estimate its lithiation range. Conversely, an initial guess of the lithiation range can be made for the OCP curve obtained from technical literature. The correlation between the peaks of the known electrode and those of the cell OCV profile can be assessed through the pseudo-inverse matrix method. As the plots 700 of FIG. 7 illustrate, by examining the coupling between the inverse of the differential capacity curves for the full cell and known electrodes (dOCV/dSOC and dU/dx), and the coupling between the inverse of their corresponding first derivatives (d²OCV/dSOC² and d²U/dx²), a clear correspondence between the peaks of the cell and those of the electrode can be observed. After such peaks are manually identified, the lithiation ranges are determined as:

$$[ \begin{matrix}{x}_{A} \\ {x}_{B} \\ {x}_{C}\end{matrix} ] = [ \begin{matrix}1 - {SOC}_{A} & {SOC}_{A} \\ 1 - {SOC}_{B} & {SOC}_{B} \\ 1 - {SOC}_{C} & {SOC}_{C}\end{matrix} ] [ \begin{matrix}{x}_{pse}^{0} \\ {x}_{se}^{f}\end{matrix} ] \to [ \begin{matrix}{x}_{pse}^{0} \\ {x}_{se}^{f}\end{matrix} ] = {[ \begin{matrix}1 - {SOC}_{A} & {SOC}_{A} \\ 1 - {SOC}_{B} & {SOC}_{B} \\ 1 - {SOC}_{C} & {SOC}_{C}\end{matrix} ]}^{⊤} [ \begin{matrix}{x}_{A} \\ {x}_{B} \\ {x}_{C}\end{matrix} ] , \qquad ( 9 )$$

where τ indicates the pseudo-inverse. The plots 800 of FIG. 8 show that the electrode curve can be shifted using the SOC (x) mathematical relation expressed in Equation (8), and the lithiation ranges identified through the pseudo-inverse matrix method. This adjustment leads to a better alignment of the electrode's peaks of interest with those of the full cell.

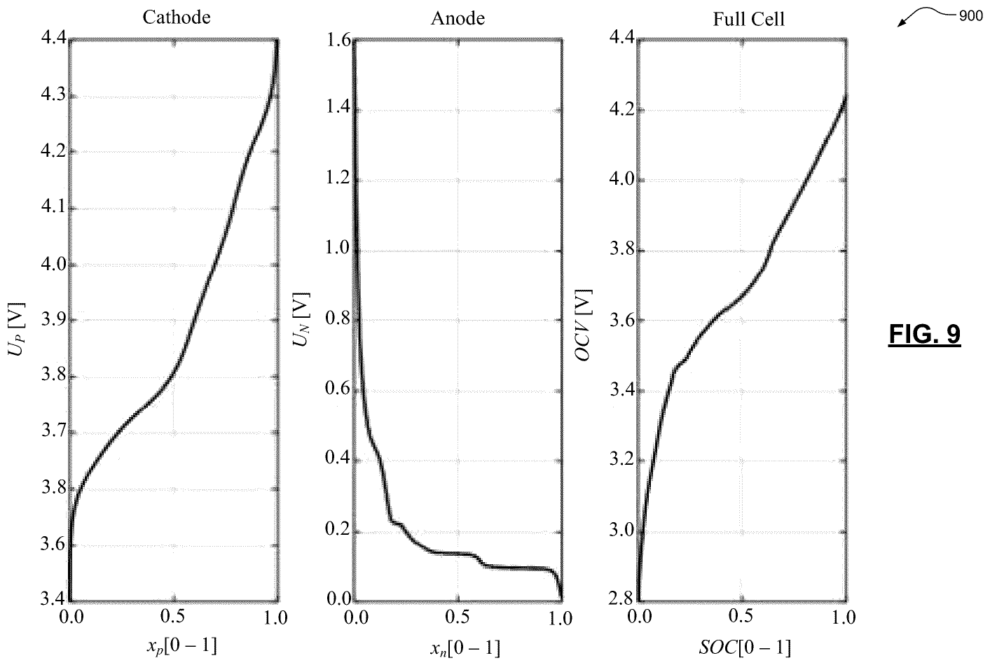

Step 240 involves estimating the OCP of the unknown (second) electrode from cell OCV measurements. After the known electrode OCP is reconstructed from literature data, the OCP of the unknown electrode, along with the lithiation ranges for both electrodes, are estimated based upon cell OCV measurements. This procedure generally comprises three steps. First (1), data loading and pre-processing is performed. The OCP curve of the known electrode obtained from the reconstruction process outlined in step 216, as well as experimental OCV data obtained from the full cell in step 232 are loaded. A standardized convention has been established regarding the electrodes OCP and full cell OCV to ensure the proper execution of the reconstruction algorithm, regardless of whether the cell undergoes charging or discharging when obtaining the OCV data. The plots 900 of FIG. 9 show the convention adopted for the electrodes and the full cell terminal voltage. For the cathode, the maximum OCP value is when xₚ≃1 and the minimum OCP value is when xₚ≃0. For the anode, the maximum OCP value when xₙ≃0 and the minimum OCP value is when xₙ≃1. For the full cell, the maximum OCV value when SOC=1, and minimum OCV value when SOC=0. To execute the algorithm, the input data (full cell OCV and known electrode OCP) must be rearranged to comply with this convention. Additionally, numerically differentiation and fine-tuning of the derivative rate (ΔV) is necessary to achieve a good trade-off between noise and the quality of the resulting differential capacity diagrams.

Next (2), a suitable initial guess for the parameters and constraints is defined. To effectively guide the optimization algorithm towards a feasible solution, it is crucial to provide an initial guess for the parameters and to define box constraints on their range. Table 2 below shows the parameters classified for the known and unknown electrode. For the unknown electrode, the number of reactions N, along with the initial parameters of the MSMR model, are determined using information obtained from technical literature (step 204). While the available information may not be entirely accurate or specifically descriptive of the electrode material under analysis, they can still provide a good initial approximation. The range of variation of each parameter of the MSMR model must be selected as a trade-off between exploration and computation time. To assist in this decision, it is worth noting that a smaller range may be set if the available information is considered reliable, while a larger range of variation must be chosen if there is uncertainty in the data obtained for the known electrode. Since prior information regarding the lithiation ranges is unavailable, these values are arbitrarily searched within a defined interval that may be arbitrary set. The electrode OCP curve is then estimated between the defined maximum and minimum voltage values. For the known electrode, while the lithiation ranges identified with the pseudo-inverse matrix method in step 236 offer a reasonable approximation, it is beneficial to allow some flexibility in these values during optimization. As with the MSMR parameters, a range of variation is attributed to these parameters to limit the search space during optimization.

TABLE 2
Unknown Electrode

| | |
|---|---|
| N | Number of reactions that occur in the material |
| ${U}_{0}^{0} , {X}_{0} , {w}_{0}$ | Initial MSMR model parameters |
| ΔU⁰, ΔX, Δw | Range of variation for MSMR parameters |
| Uₘᵢₙ, Uₘₐₓ | Voltage boundaries for the reconstructed OCP |
| ${x}_{lb}^{0} , {x}_{ub}^{0} , {x}_{lb}^{f} , {x}_{ub}^{f}$ | Bound of lithiation ranges |
| W, α | Optimization weights |

Known Electrode

| | |
|---|---|
| Δx⁰, Δx^{f} | Range of variation for lithiation ranges |

Finally (3), the optimization problem is solved. As a reminder, the known electrode's OCP curve is reconstructed from literature and processed from step 208 to step 228. The unknown (second) electrode requires estimation of its OCP curve from cell terminal voltage data. The problem under consideration is a large-scale, non-linear optimization problem. Given its characteristics, the solver utilized could be a particle swarm optimization (PSO). With its capacity to handle large number of optimization variables and being gradient-free, PSO is efficient in searching the feasible space and finding a solution for the problem. For the algorithm, the following notation is introduced: (i) subscript k denotes the known electrode (reconstructed from literature), e.g., Uₖ(SOCₖ(xₖ)), and (ii) subscript denotes the unknown electrode (whose OCP shall be estimated from full cell OCV), e.g., Uᵤ(SOCᵤ(xᵤ)).

Computing the cost function for the optimization problem, as formulated in Equation (12) shown below, involves the following steps:
(1) compute Uₖ(SOCₖ(\tilde{x}ₖ)): the lithiation ranges

$${\hat{x}}_{k}^{0} and {\hat{x}}_{k}^{f}$$

of the known electrode are set, enabling evaluation of the curve Uₖ(SOCₖ(\tilde{x}ₖ)) according to the relation

$${SOC}_{k} ( {\tilde{x}}_{k} ) = \frac{{\tilde{x}}_{k} - {\hat{x}}_{k}^{0}}{{\tilde{x}}_{k}^{f} - {\hat{x}}_{k}^{0}} ,$$

with

$${\tilde{x}}_{k} ∈ [ {\hat{x}}_{k}^{0} , {\hat{x}}_{k}^{f} ] ;$$

(2) generate an estimate for the Ûᵤ(\tilde{x}ᵤ) curve using the 3×N MSMR parameters: given an input Uᵤ∈[U_{u,min}, U_{u,max}], and using the MSMR model formulation:

$${\tilde{x}}_{u} ( {U}_{u} ) = {\sum }_{j} \frac{{X}_{j}}{1 + exp \vert \frac{f ( {U}_{u} - {U}_{j}^{0} )}{{w}_{j}} \vert} \qquad ( 10 )$$

$$0 < {\tilde{x}}_{u} ( {U}_{u} ) < 1 ,$$

the curve Ûᵤ(\tilde{x}ᵤ) is consequently generated;

(3) compute Ûᵤ(SOCᵤ(\tilde{x}ᵤ)): the lithiation ranges

$${\hat{x}}_{u}^{0} and {\hat{x}}_{u}^{f}$$

of the unknown electrode are set, enabling evaluation of the curve Ûᵤ(SOCᵤ(\tilde{x}ᵤ)) according to the relation

$${SOC}_{u} ( {\tilde{x}}_{u} ) = \frac{{\tilde{x}}_{u} - {\hat{x}}_{u}^{0}}{{\hat{x}}_{u}^{f} - {\hat{x}}_{u}^{0}} ,$$

with

$${\tilde{x}}_{u} ∈ [ {\hat{x}}_{u}^{0} , {\hat{x}}_{u}^{f} ] ;$$

and

(4) compute cell terminal voltage from reconstructed electrode OCP and estimated electrode OCP:

$$( SOC ) = {U}_{p} ( {SOC}_{p} ( {\tilde{x}}_{p} ) ) - {U}_{n} ( {SOC}_{n} ( {\tilde{x}}_{n} ) ) . \qquad ( 11 )$$

Moreover, by defining the vector SOC∈[0, 1], the incremental capacity curve [symbol] is computed through numerical differentiation of [symbol] (SOC).

The optimization problem is thereafter defined as follows:

$${min}_{θ} J = ( 1 - W ) \cdot {J}_{1} + W \cdot {J}_{2} + {J}_{pen} \qquad ( 12 )$$

subject to:

$${U}_{0 , j}^{0} - Δ {U}_{j}^{0} \leq {U}_{j}^{0} \leq {U}_{0 , j}^{0} + Δ {U}_{j}^{0}$$

$${X}_{0 , j} - Δ {X}_{j} \leq {X}_{j} \leq {X}_{0 , i} + Δ {X}_{j}$$

$${w}_{0 , j} - Δ {w}_{j} \leq {w}_{j} \leq {w}_{0 , j} + Δ {w}_{j} ,$$

$${x}_{u , lb}^{0} \leq {\hat{x}}_{u}^{0} \leq {x}_{u , ub}^{0}$$

$${x}_{u , lb}^{f} \leq {\hat{x}}_{u}^{f} \leq {x}_{u , ub}^{f} , and$$

$${x}_{k , pse}^{0} - Δ {x}_{k}^{0} \leq {\hat{x}}_{k}^{0} \leq {x}_{k , pse}^{0} + Δ {x}_{k}^{0}$$

$${x}_{k , pse}^{f} - Δ {x}_{k}^{f} \leq {\hat{x}}_{k}^{f} \leq {x}_{k , pse}^{f} + Δ {x}_{k}^{f} ,$$

$$where :$$

$${J}_{1} = \frac{\sqrt{\frac{1}{n} {\sum }_{i}^{n} {( ( {OC V}_{i} - ) \cdot α )}^{2}}}{{e}_{OC V , max}} ,$$

$${J}_{2} = \frac{\sqrt{\frac{1}{n} {\sum }_{i}^{n} {( ( \frac{dCOS}{{dOC V}_{i}} - \frac{{dOC V}_{ι}}{} ) \cdot α )}^{2}}}{{e}_{\frac{dx}{d V} , max}} , and$$

$$θ = [ {U}_{1}^{0} , {X}_{1} , {w}_{1} , … , {U}_{N}^{0} , {X}_{N} , {w}_{N} , {\hat{x}}_{n}^{0} , {\hat{x}}_{n}^{f} , {\hat{x}}_{p}^{0} , {\hat{x}}_{p}^{f} ] .$$

Solution of the above problem produces a set of [3×N+4] parameters, where [3×N] parameters are related to the MSRM model and four parameters are related to the anode and cathode lithiation ranges. The J₁ term denotes the error on the terminal voltage curve, while J₂ represents the error on the incremental capacity curve. Both terms are normalized for the maximum tolerable errors e_{OCV,max} and e_{dx/dV, max}. These terms can be adjusted by tuning the coefficient α to prioritize various sections of the curve. The two terms are then combined with a tunable weight W. An addition term Jₚₑₙ is used to penalize the cost function in case additional physics-related constraints are violated. The constraints are mainly categorized into three sets: (1) MSMR constraints (set in accordance with literature to help generating a physically consistent electrode curve); (2) unknown electrode lithiation ranges constraints (while no previous knowledge exists regarding these values, reasonable values can be arbitrarily chosen); and (3) known electrode lithiation ranges constraints (while the pseudo-inverse matrix method offers a good approximation of the lithiation ranges, allowing these parameters to fluctuate within a restricted and defined interval improves the convergence rate of the PSO algorithm to a solution).

Step 244 involves computing a final output of the procedure or method 200 (e.g., the OCP estimate). The procedure yields the following outputs: (1) an enhanced representation of OCP for the known electrode, Uₖ(SOCₖ(\tilde{x}ₖ)); (2) an estimate of unknown electrode OCP, using the optimization procedure; and (3) an Identification of lithiation ranges for both cathode and anode curves. The objective of the optimization procedure is to minimize errors in both the full cell OCV curve and the cell incremental capacity curve, while simultaneously ensuring adherence to physical constraints. Various weights (W) can be tested to yield different outcomes.

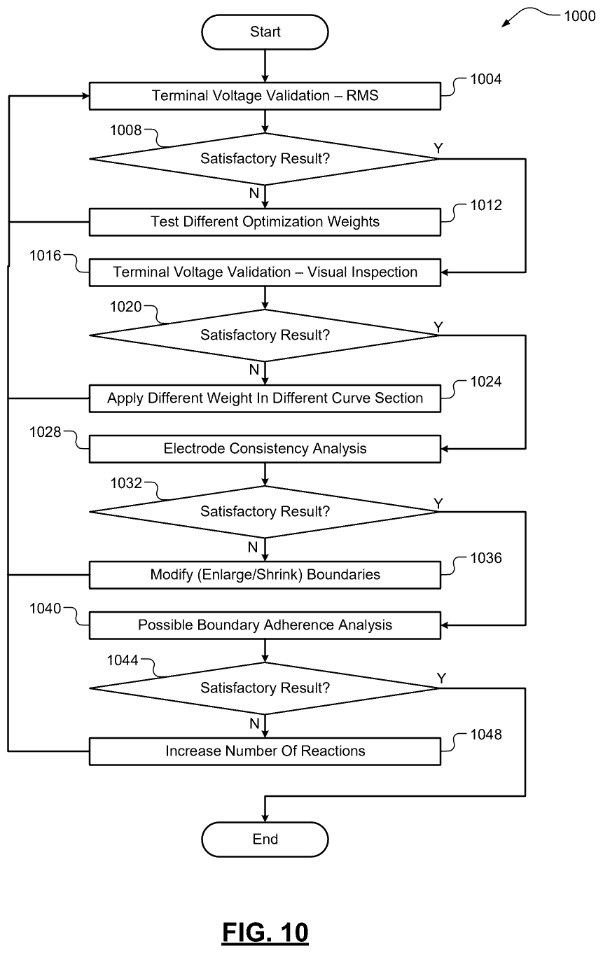

Finally, steps 248-252 involve performing error analysis. Due to the nonlinearity of the optimization problem and the large number of variables, there is potential for the existence of multiple local minima, which could significantly change the shape of the estimated OCP curve Ûᵤ(SOCᵤ(\tilde{x}ᵤ)). For this reason, the feasibility and consistency of the estimated OCP curve can be assessed by conducting a series of sanity checks on the available outputs (step 244) and by evaluating the solution process of the PSO algorithm. To this extent, an error detection strategy has been created, along with potential remediation solutions for result enhancement if some of the following assessments are not satisfied. Three primary assessments need to be conducted, which are described more fully below. FIG. 10 illustrates a flow diagram of an example method 1000 summarizing the assessments, prioritized according to their importance. Given the complexity of the problem and the numerous variables involved, providing a unique solution for each error type that will guarantee results enhancement is unrealistic. However, FIG. 10 outlines a systematic strategy to iteratively execute the algorithm, generating diverse solutions. From these options, the one that best aligns with the expected or desired attributes should be chosen.

This iterative method 1000 enables exploration of various possibilities and identification of the most suitable solution that better satisfies the consistency checks. In a first assessment (steps 1004-1024), cell OCV validation is performed. The objective of the optimization problem is to calibrate the lithiation ranges for both electrodes while estimating the OCP curve of the unknown electrode. This should result in a low prediction error for the full cell OCV and its differential capacity. For this purpose, two distinct evaluations are necessary. The first is an RMS computation (step 1004). The RMS is a valuable indicator to evaluate the overall correctness of the OCV curve fit. A lower RMS error indicates that the fit closely approximates the experimental data. If unsatisfactory (step 1008), different optimization weights could be tested (step 1012). The second is a visual inspection (step 1016). While the RMS error offers a good overall indication of the fitting error, it does not provide information concerning specific areas of the cell OCV curve. By visually inspecting the OCV curve resulting from applying step 240, potential mismatches can be detected. If unsatisfactory (step 1020), different weights could be applied in difference curve sections (step 1024).

In a second assessment (steps 1028-1036), the electrode OCP physical consistency is evaluated. Despite the limited information on the electrodes, their OCP curves and lithiation ranges must be realistic and consistent with physical insights. Through visual inspection of the curves, any unrealistic behaviors (e.g., discontinuities, sharp jumps, entirely flat plateaus, etc.) can be detected. Similarly, reactions localized in unusual or unexpected positions can also be identified. If unsatisfactory (step 1032), the boundaries can be adjusted or modified (e.g., enlarged or shrunk) (step 1036). A final third assessment (steps 1040-1048) involves determining whether the optimization variables are saturated (step 1040). Applying box constraints to the variables of the optimization problem is crucial to guide the identification process towards the best solution. However, given the large number of variables, it is expected that some may saturate to the boundaries. Nonetheless, monitoring the final values of the optimization variables is essential to understand whether the optimizer converged to a solution within the feasible domain or if the defined constraints have somehow limited the search. If unsatisfactory (step 1044), the number of reactions N could be increased (step 1048).

It will be appreciated that the terms “controller” and “control system” as used herein refer to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. An open-circuit potential (OCP) estimation system for a battery system of an electrified vehicle, the OCP estimation system comprising:
a set of sensors configured to measure a set of operating parameters of a battery cell of the battery system, the battery cell being a lithium-ion type battery cell and comprising two electrodes; and
a computing device configured to perform an OCP estimation process based on the measured set of operating parameters, the OCP estimation process further including:
obtaining known information relating to the two electrodes;
identifying one of the two electrodes as a known electrode based on the known information;
applying a physics-based model to reconstruct an OCP curve for the known electrode;
determining lithiation ranges of the other of the two electrodes based on experimental test results for the battery cell;
reconstructing an OCP curve for the other of the two electrodes based on its lithiation ranges; and
generating a final estimate of the OCP of the two electrodes of the battery cell based on the reconstructed OCP curves.

2. The OCP estimation system of claim 1, wherein the battery cell is not physically disassembled.

3. The OCP estimation system of claim 1, wherein the known information for the two electrodes includes properties of materials forming the two electrodes, and wherein the known electrode is identified as having more known information.

4. The OCP estimation system of claim 3, wherein the computing device is further configured to determine an electrode data quality score for each of the two electrodes based on the known information and identify the known electrode as having the higher electrode data quality score.

5. The OCP estimation system of claim 1, wherein the computing device is further configured to apply a multi-scale-multi-reaction (MSMR) model to reconstruct the OCP curve for the known electrode based on its known information.

6. The OCP estimation system of claim 5, wherein the computing device is further configured to correct the reconstructed OCP curve for the known electrode based on whether its phase transition locations are known and whether peaks predicted by the MSMR model are coherent.

7. The OCP estimation system of claim 1, wherein the computing device is further configured to perform an experimental test for the battery cell as a whole to determine the experimental test results including an open-circuit voltage (OCV) measurement for the battery cell.

8. The OCP estimation system of claim 7, wherein the computing device is further configured to determine an initial guess of the lithiation ranges for the other of the two electrodes of the battery cell and to shift and/or rescale the reconstructed OCP curve for the other of the two electrodes to match with the battery cell OCV measurement.

9. The OCP estimation system of claim 8, wherein the computing device is further configured to solve a constrained optimization problem to generate the final estimate of the OCP of the two electrodes of the battery cell.

10. The OCP estimation system of claim 9, wherein the computing device is further configured to perform an error analysis for the final estimate of the OCP of the two electrodes of the battery cell, the error analysis including (i) root-mean-square (RMS) based terminal voltage validation, (ii) visual inspection terminal voltage validation, (iii) electrode consistence analysis, and (iv) boundary adherence analysis.

11. An open-circuit potential (OCP) estimation method for a battery system of an electrified vehicle, the OCP estimation system comprising:
measuring, by a set of sensors, a set of operating parameters of a battery cell of the battery system, the battery cell being a lithium-ion type battery cell and comprising two electrodes; and
performing, by a computing device associated with the electrified vehicle, an OCP estimation process based on the measured set of operating parameters, the OCP estimation process further including:
obtaining known information relating to the two electrodes;
identifying one of the two electrodes as a known electrode based on the known information;
applying a physics-based model to reconstruct an OCP curve for the known electrode;
determining lithiation ranges of the other of the two electrodes based on experimental test results for the battery cell;
reconstructing an OCP curve for the other of the two electrodes based on its lithiation ranges; and
generating a final estimate of the OCP of the two electrodes of the battery cell based on the reconstructed OCP curves.

12. The OCP estimation method of claim 11, wherein the OCP estimation method does not include physically disassembling the battery cell.

13. The OCP estimation method of claim 11, wherein the known information for the two electrodes includes properties of materials forming the two electrodes, and wherein the known electrode is identified as having more known information.

14. The OCP estimation method of claim 13, further comprising determining, by the computing device, an electrode data quality score for each of the two electrodes based on the known information and identify the known electrode as having the higher electrode data quality score.

15. The OCP estimation method of claim 11, further comprising applying, by the computing device, a multi-scale-multi-reaction (MSMR) model to reconstruct the OCP curve for the known electrode based on its known information.

16. The OCP estimation method of claim 15, further comprising correcting, by the computing device, the reconstructed OCP curve for the known electrode based on whether its phase transition locations are known and whether peaks predicted by the MSMR model are coherent.

17. The OCP estimation method of claim 11, further comprising performing, by the computing device, an experimental test for the battery cell as a whole to determine the experimental test results including an open-circuit voltage (OCV) measurement for the battery cell.

18. The OCP estimation method of claim 17, further comprising determining, by the computing device, an initial guess of the lithiation ranges for the other of the two electrodes of the battery cell and then shifting and/or rescaling, by the computing device, the reconstructed OCP curve for the other of the two electrodes to match with the battery cell OCV measurement.

19. The OCP estimation method of claim 18, further comprising solving, by the computing device, a constrained optimization problem to generate the final estimate of the OCP of the two electrodes of the battery cell.

20. The OCP estimation method of claim 19, further comprising performing, by the computing device, an error analysis for the final estimate of the OCP of the two electrodes of the battery cell, the error analysis including (i) root-mean-square (RMS) based terminal voltage validation, (ii) visual inspection terminal voltage validation, (iii) electrode consistence analysis, and (iv) boundary adherence analysis.
